(19) United States
(12) Patent Application Publication
(10) Pub. No.: US 2024/0202406 A1
(43) Pub. Date: Jun. 20, 2024

(54) STRUCTURAL ANALYSIS METHOD AND INFORMATION PROCESSING APPARATUS

(71) Applicant: Fujitsu Limited, Kawasaki-shi (JP)

(72) Inventor: Amir HADERBACHE, Kawasaki (JP)

(73) Assignee: Fujitsu Limited, Kawasaki-shi (JP)

(21) Appl. No.: 18/366,728

(22) Filed: Aug. 8, 2023

(30) Foreign Application Priority Data
Dec. 16, 2022 (JP) 2022-201127

(51) Int. Cl. G06N 3/0464

(52) U.S. Cl. CPC G06N 3/0464

(57) ABSTRACT

An information processing apparatus generates a feature vector for each of a plurality of nodes included in an element in mesh data, based on a location of the corresponding node, an elastic modulus at the corresponding node, and stress applied to the corresponding node. The information processing apparatus enters the feature vectors of the nodes to a trained machine learning model, performs a convolutional operation on the feature vectors of the nodes, and estimates an element stiffness matrix indicating stiffness of the element based on a result of the convolutional operation.

### CROSS-REFERENCE TO RELATED APPLICATION

This application is based upon and claims the benefit of priority of the prior Japanese Patent Application No. 2022-201127, filed on Dec. 16, 2022, the entire contents of which are incorporated herein by reference.

### FIELD

The embodiments relate to a structural analysis method and an information processing apparatus.

### BACKGROUND

A structural analysis simulation is known as a computer simulation. In the structural analysis simulation, a computer computes mechanical properties of an object, based on force that the object receives from the outside. Examples of the mechanical properties include stress caused in the object and a displacement amount caused when the object is deformed. There are cases in which a finite element method, which is a numerical analysis method, is used for the structural analysis simulation.

In the finite element method, the shape of an object is divided into a plurality of elements. Each element is a small region such as a tetrahedron or a hexahedron, and includes a plurality of nodes and a plurality of edges, each of which connects nodes. In the finite element method, a variable is assigned to an individual node or edge, and a simultaneous linear equation that discretely expresses a relationship among these variables is generated. In the finite element method, by solving this generated simultaneous linear equation, an approximate solution of an equation that is difficult to solve analytically is computed.

In the finite element method in the structural analysis simulation, there are cases in which a simultaneous linear equation is defined by generating a stiffness matrix. The stiffness matrix represents stiffness, which indicates how much an object is resistant to deformation due to external force. In the structural analysis simulation, there are cases in which the generation of the stiffness matrix and the solving of the simultaneous linear equation are iteratively executed, depending on the purpose of the simulation.

There has been proposed a deep learning system that generates a normalized finite element, computes correct strain for the finite element, and trains a deep learning network such that a B matrix representing a relationship between a displacement amount and a strain is estimated from shape information.

See, for example, Publication of U.S. Patent Application No. 2022/0129520.

### SUMMARY

In one aspect of the embodiments, there is provided a non-transitory computer-readable recording medium storing therein a computer program that causes a computer to execute a process including: generating a feature vector for each node of a plurality of nodes included in an element in mesh data, based on a location of the node, an elastic modulus at the node, and stress applied to the node; entering feature vectors of the plurality of nodes to a trained machine learning model; performing a convolutional operation on the feature vectors of the plurality of nodes; and estimating an element stiffness matrix indicating stiffness of the element based on a result of the convolutional operation.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 illustrates an information processing apparatus according to a first embodiment;

FIG. 2 illustrates a hardware example of an information processing apparatus according to a second embodiment;

FIG. 3 illustrates a procedure example of estimation of an element stiffness matrix;

FIG. 4 illustrates an example of a feature vector;

FIG. 5 illustrates an example of an element stiffness matrix;

FIG. 6 illustrates examples of adjacency matrixes;

FIG. 7 illustrates an example of normalization of an element stiffness matrix;

FIG. 8 illustrates an example of a graph convolutional operation;

FIG. 9 illustrates the first half of a construction example of a machine learning model;

FIG. 10 illustrates the second half of the construction example of the machine learning model;

FIG. 11 is a block diagram illustrating a functional example of the information processing apparatus;

FIG. 12 is a flowchart illustrating a procedure example of machine learning;

FIG. 13 is a flowchart illustrating a procedure example of a simulation;

FIG. 14 is a graph illustrating an example of an estimation error of an element stiffness matrix; and

FIG. 15 is a graph illustrating an example of the execution time of generation of an element stiffness matrix.

### DESCRIPTION OF EMBODIMENTS

In a structural analysis simulation, there are cases in which a stiffness matrix is generated from parameter values determined when the simulation is executed. However, in the structural analysis simulation, the load of generating the stiffness matrix could be relatively high. Thus, there are cases in which the generation of the stiffness matrix results in a bottleneck, and the execution time of the structural analysis simulation is extended.

Hereinafter, the present embodiments will be described with reference to the accompanying drawings.

### First Embodiment

A first embodiment will be described.

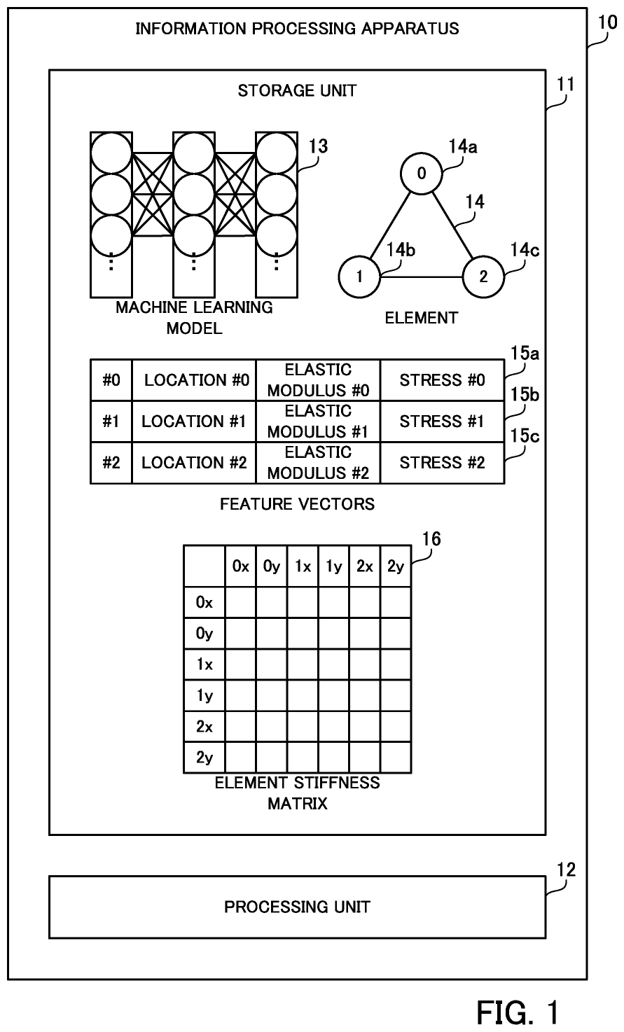

FIG. 1 illustrates an information processing apparatus according to the first embodiment.

This information processing apparatus 10 according to the first embodiment generates a stiffness matrix used for a structural analysis simulation by using a trained machine learning model. The information processing apparatus 10 may perform a structural analysis simulation by using a stiffness matrix that has already been generated. Alternatively, the information processing apparatus 10 may train a machine learning model by using training data. The information processing apparatus 10 may be referred to as a computer, a structural analysis apparatus, or a stiffness matrix generation apparatus. The information processing apparatus 10 may be a client apparatus or a server apparatus.

The information processing apparatus 10 includes a storage unit 11 and a processing unit 12. The storage unit 11 may be a volatile semiconductor memory such as a random access memory (RAM) or a non-volatile storage such as a hard disk drive (HDD) or a flash memory.

The processing unit 12 is, for example, a processor such as a central processing unit (CPU), a graphics processing unit (GPU), or a digital signal processor (DSP). The processing unit 12 may include an electronic circuit such as an application specific integrated circuit (ASIC) or a field programmable gate array (FPGA). The processor executes a program stored in a memory such as a RAM (such as the storage unit 11), for example. A group of processors may be referred to as a multi-processor or simply “processor”.

The storage unit 11 stores a trained machine learning model 13. The machine learning model 13 may be a machine learning model that has already been trained by another information processing apparatus. The machine learning model 13 performs a convolutional operation when computing an estimated value from input feature amounts. The convolutional operation includes a process of adding, to a feature amount, a converted value of another feature amount having an adjacency relationship with the feature amount. The training of the machine learning model 13 includes, for example, determining parameter values used for conversion of feature amounts. The machine learning model 13 may be a neural network, a convolutional neural network, or a graph convolutional neural network.

The processing unit 12 acquires an element 14 included in mesh data. The element 14 is one of the small regions obtained by dividing the shape of a simulation target object. The element 14 may be a two-dimensional (2D) region or a three-dimensional (3D) region. The element 14 is generated by a computer aided design (CAD) software, for example. The element 14 is, for example, a triangle, a rectangle, a tetrahedron, or a hexahedron.

The element 14 includes a plurality of nodes and a plurality of edges, each of which connects nodes. The plurality of nodes and the plurality of edges define the borders of the element 14. The number of nodes and the number of edges are determined by the topology of the element 14. If the element 14 is a triangle, the number of nodes is 3. If the element 14 is a rectangle, the number of nodes is 4. If the element 14 is a tetrahedron, the number of nodes is 4. If the element 14 is a hexahedron, the number of nodes is 8. For example, the element 14 includes nodes 14a, 14b, and 14c (nodes #0, #1, and #2).

The processing unit 12 generates a feature vector for each of the plurality of nodes included in the element 14. For example, the processing unit 12 generates feature vectors 15a, 15b, and 15c for the nodes 14a, 14b, and 14c, respectively. Specifically, the processing unit 12 generates a feature vector for a node, based on the location of the node, the elastic modulus at the node, and the stress applied to the node. The processing unit 12 may additionally use other feature amounts.

Each feature vector may be a vector including a feature amount indicating a location, a feature amount indicating an elastic modulus, and a feature amount indicating stress. For example, the location of a node is expressed by 2D or 3D coordinates in a Cartesian coordinate system. The elastic modulus at a node is a coefficient included in an elastic matrix computed from the material of the target object, for example. The stress applied to a node is a coefficient included in a 3D or six-dimensional (6D) stress vector, for example. The stress applied to the node may be stress computed in the previous time step in the simulation.

The processing unit 12 enters the feature vectors of the plurality of nodes included in the element 14 to the machine learning model 13. The machine learning model 13 performs a convolutional operation on the feature vectors of the plurality of nodes. For example, the processing unit 12 enters the feature vectors 15a, 15b, and 15c to the machine learning model 13, and the machine learning model 13 performs a convolutional operation on the feature vectors 15a, 15b, and 15c.

The processing unit 12 may generate an adjacency matrix indicating an adjacency relationship among the plurality of nodes and may enter the adjacency matrix to the machine learning model 13. The machine learning model 13 may refer to the adjacency matrix when performing the convolutional operation on the plurality of feature vectors.

This adjacency matrix may be denser than a regular adjacency matrix, which indicates presence or absence of an individual edge. For example, the adjacency matrix indicates that all the nodes included in the element 14 are adjacent to each other.

The processing unit 12 estimates an element stiffness matrix 16 indicating the stiffness of the element 14, based on the result of the convolutional operation. The stiffness indicates resistance to deformation due to external force. For example, the machine learning model 13 outputs the element stiffness matrix 16 as an estimated value. In this case, the processing unit 12 may skip a regular matrix generation process based on finite element method software. The processing unit 12 may perform the estimation process by using a hardware accelerator such as a GPU. The element stiffness matrix 16 is, for example, a square matrix and also a symmetric matrix. The length of the individual side of the element stiffness matrix 16 is a sum of the degrees of freedom of the plurality of nodes included in the element 14, for example.

The processing unit 12 may estimate a different element stiffness matrix corresponding to a different element and may estimate the element stiffness matrix 16 and the different element stiffness matrix in parallel. The processing unit 12 may generate an overall stiffness matrix corresponding to an overall object shape including the plurality of elements, by using the element stiffness matrix 16 corresponding to the element 14. For example, the processing unit 12 adds a coefficient corresponding to two independent variables in the element stiffness matrix 16 to a coefficient corresponding to the two independent variables in the overall stiffness matrix.

The processing unit 12 may define a simultaneous linear equation by using the element stiffness matrix 16 or the overall stiffness matrix and may compute a solution of the simultaneous linear equation by using a linear solver. For example, regarding a displacement vector x, the processing unit 12 solves Ax=b in which A is the overall stiffness matrix, x is the displacement vector, and b is the force vector. The processing unit 12 may compute the location of each node after the displacement, based on the computed displacement vector x. The processing unit 12 may compute the stress applied to each node by using an equation expressing the relationship between the displacement and the strain and by using an equation expressing the relationship between the strain and the stress.

The processing unit 12 may compute an approximate solution of a non-linear equation based on a Newton-Raphson method. In this case, the generation of the element stiffness matrix 16 and the solving of the simultaneous linear equation may be executed iteratively. In addition, the processing unit 12 may compute the displacement and stress of an individual node at an individual time by advancing the time step by step based on a time marching method. In this case, the generation of the element stiffness matrix 16 and the solving of the simultaneous linear equation may be executed iteratively.

As described above, the information processing apparatus 10 according to the first embodiment generates the feature vectors of the nodes 14a, 14b, and 14c included in the element 14 in the mesh data, based on the location, elastic modulus, and stress of these nodes. By entering these feature vectors to the machine learning model 13, the information processing apparatus 10 performs a convolutional operation on the feature vectors of the nodes 14a, 14b, and 14c and estimates the element stiffness matrix 16 indicating the stiffness of the element 14.

In this way, the information processing apparatus 10 generates the element stiffness matrix 16 more quickly than a regular matrix generation process based on finite element software. Thus, the information processing apparatus 10 shortens the execution time of the structural analysis simulation. In addition, the estimation process performed by the machine learning model 13 is parallelized easily, and the overhead that occurs when the parallelism is increased is relatively small. Thus, a plurality of element stiffness matrixes corresponding to a plurality of elements are generated quickly.

The machine learning model 13 may be a graph convolutional neural network. In this way, the machine learning model 13 is able to estimate element stiffness matrixes for elements of various topologies such as a tetrahedron and a hexahedron. In addition, by using a GPU, the information processing apparatus 10 may estimate element stiffness matrixes corresponding to a plurality of elements in parallel. In this way, the matrix generation process is performed quickly on mesh data including a plurality of elements.

The information processing apparatus 10 may generate an adjacency matrix indicating that each of the plurality of nodes included in the element 14 is adjacent to all the other nodes and may perform the convolutional operation based on this adjacency matrix. In this way, the result of an F-bar method used for a matrix generation process based on finite element method software is accurately reproduced, and the accuracy of the element stiffness matrix 16 is improved.

Information about the location of a node may include the initial location of the node and the displacement amount of the node computed in the previous time step in the simulation. The information processing apparatus 10 may generate a feature vector by additionally using a shape differentiation matrix indicating differentiation of an interpolation function. In this way, the estimation accuracy of the element stiffness matrix 16 is further improved.

In addition, the information processing apparatus 10 may generate training data including feature vectors and correct element stiffness matrixes by executing a finite element method simulation and may train the machine learning model 13 by using this training data. In this way, the machine learning model 13 capable of accurately estimating the element stiffness matrix 16 is generated.

### Second Embodiment

Next, a second embodiment will be described.

An information processing apparatus 100 according to the second embodiment executes a structural analysis simulation to analyze temporal and spatial change in object structure due to external force. In addition, the information processing apparatus 100 performs machine learning to generate a machine learning model for estimating an element stiffness matrix. The information processing apparatus 100 estimates an element stiffness matrix by using a trained machine learning model, instead of performing matrix generation based on the F-bar method. The execution of the machine learning and the estimation of the element stiffness matrix may be performed by different information processing apparatuses.

The information processing apparatus 100 may be used for automobile production, material development, disaster management, etc. The information processing apparatus 100 may be a client apparatus or a server apparatus. The information processing apparatus 100 may be referred to as a computer, a simulation apparatus, a structural analysis apparatus, or a machine learning apparatus. The information processing apparatus 100 corresponds to the information processing apparatus 10 according to the first embodiment.

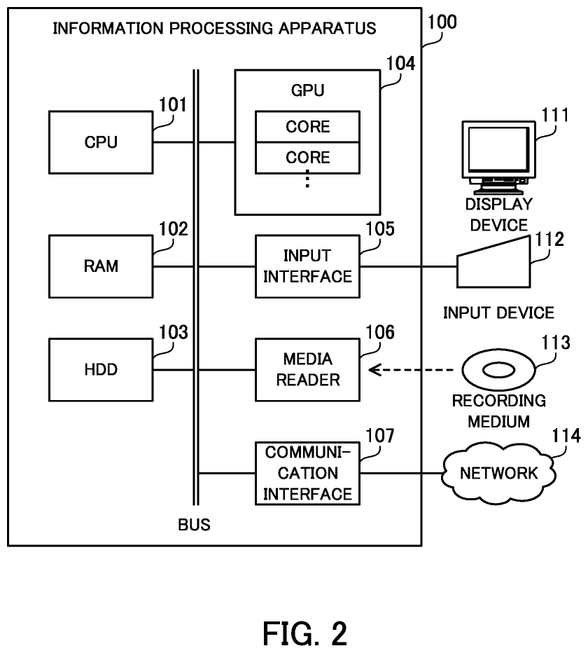

FIG. 2 illustrates a hardware example of the information processing apparatus according to the second embodiment.

The information processing apparatus 100 includes a CPU 101, a RAM 102, an HDD 103, a GPU 104, an input interface 105, a media reader 106, and a communication interface 107, each of which is connected to a bus. The CPU 101 corresponds to the processing unit 12 according to the first embodiment. The RAM 102 or the HDD 103 corresponds to the storage unit 11 according to the first embodiment.

The CPU 101 is a processor that executes program instructions. The CPU 101 loads a program and data stored in the HDD 103 to the RAM 102 and executes the program. The information processing apparatus 100 may include a plurality of processors.

The RAM 102 is a volatile semiconductor memory that temporarily stores a program executed by the CPU 101 and data used for computation by the CPU 101. The information processing apparatus 100 may include a different kind of volatile memory other than a RAM.

The HDD 103 is a non-volatile storage that stores an operating system (OS), middleware, software programs such as application software, and data. The information processing apparatus 100 may include a different kind of non-volatile storage, such as a flash memory or a solid state drive (SSD).

The GPU 104 performs image processing in coordination with the CPU 101 and outputs an image to a display device 111 connected to the information processing apparatus 100. Examples of the display device 111 include a cathode ray tube (CRT) display, a liquid crystal display (LCD), an organic electro-luminescence (EL) display, and a projector. A different kind of output device such as a printer may be connected to the information processing apparatus 100.

The GPU 104 may be used as a general purpose computing on graphics processing unit (GPGPU). The GPU 104 may execute a program in accordance with an instruction from the CPU 101. The GPU 104 includes a plurality of cores. The GPU 104 may include as many as tens of thousands of cores. The plurality of cores may execute the same program on different data in parallel. The information processing apparatus 100 may include, as a GPU memory, a volatile semiconductor memory other than the RAM 102.

The input interface 105 receives an input signal from an input device 112 connected to the information processing apparatus 100. Examples of the input device 112 include a mouse, a touch panel, and a keyboard. A plurality of input devices may be connected to the information processing apparatus 100.

The media reader 106 is a reading device that reads out a program and data recorded in a recording medium 113. Examples of the recording medium 113 include a magnetic disk, an optical disc, and a semiconductor memory. The magnetic disk may be a flexible disk (FD) or an HDD. The optical disc may be a compact disc (CD) or a digital versatile disc (DVD). The media reader 106 copies a program and data read from the recording medium 113 to another recording medium such as the RAM 102 or the HDD 103. The read program may be executed by the CPU 101.

The recording medium 113 may be a portable recording medium and may be used for distribution of a program and data. The recording medium 113 and the HDD 103 may each be referred to as a computer-readable recording medium.

The communication interface 107 communicates with other information processing apparatuses via a network 114. The communication interface 107 may be a wired communication interface connected to a wired communication device such as a switch or a router. Alternatively, the communication interface 107 may be a wireless communication interface connected to a wireless communication device such as a base station or an access point.

Next, a structural analysis simulation and a stiffness matrix will be described. The information processing apparatus 100 performs a structural analysis simulation by using a finite element method. In the finite element method, the shape of an object is divided into a plurality of elements by using nodes and edges. In the finite element method, physical amounts such as the location and the stress of each element are computed by computing an approximate solution of a partial differential equation.

In the structural analysis simulation according to the second embodiment, the time marching method and the Newton-Raphson method are used. The information processing apparatus 100 uses the time marching method to compute the location and stress of each node in each of a plurality of discrete time steps. In addition, the information processing apparatus 100 uses the Newton-Raphson method to approximate a non-linear problem to a linear problem in each time step and updates the approximate solution by solving the linear problem with a linear solver.

First, the information processing apparatus 100 divides the overall shape of an object into a plurality of regions and allocates the plurality of regions to a plurality of computation nodes. For example, message passing interface (MPI) is used for this allocation of the plurality of regions. In this way, the structural analysis simulation is performed on the plurality of regions in parallel. The plurality of computation nodes may be a plurality of CPU cores, a plurality of GPU cores, a plurality of CPUs, a plurality of GPUs, or a plurality of information processing apparatuses.

In the first time step, the information processing apparatus 100 acquires mesh data including a plurality of elements, material data indicating the material of an object, and force data indicating external force applied to the object. The information processing apparatus 100 approximates a non-linear problem to a linear problem Ax=b. In this simulation, the information processing apparatus 100 generates an overall stiffness matrix. The overall stiffness matrix is used as a matrix A, for example. The overall stiffness matrix indicates a relationship between a displacement vector and a force vector. The information processing apparatus 100 solves a simultaneous linear equation by using a linear solver and updates an approximate solution of the location and stress of each node based on the solution of a vector x.

The information processing apparatus 100 repeatedly modifies the linear problem and solves the simultaneous linear equation. This repetition in the same time step may be referred to as a non-linear loop. If the information processing apparatus 100 determines that the approximate solution has converged, the information processing apparatus 100 determines the location and stress of each node in the current time step and performs the next time step. For example, if the difference between the latest approximate solution and the approximate solution in the previous iteration is less than a threshold, the information processing apparatus 100 determines that the approximate solution has converged. If the last time step specified by the user is reached, the information processing apparatus 100 ends the structural analysis simulation.

Thus, the information processing apparatus 100 iteratively generates the overall stiffness matrix until the approximate solution converges in the same time step. In addition, the information processing apparatus 100 iteratively generates the overall stiffness matrix from the first time step to the last time step. In this way, the generation of the overall stiffness matrix is performed in a dual loop.

Based on finite element method software, there is the F-bar method as a method for generating the overall stiffness matrix. However, generating the overall stiffness matrix needs high load and could occupy much of the execution time of the finite element method simulation. In addition, even if the parallelism is increased, there is a limit to improvement in processing speed due to the overhead such as the synchronization among the computation nodes. In addition, the algorithm of the F-bar method has features, such as including many small-scale loops, accessing a wide range of memory area, and having conditional branches. Thus, it is not easy for the GPU 104 to execute the algorithm of the F-bar method without modification.

The information processing apparatus 100 according to the second embodiment estimates the element stiffness matrixes of the individual elements by using a machine learning model. The machine learning model is trained to simulate a computation result obtained by the F-bar method. The information processing apparatus 100 causes the GPU 104 to perform the estimation based on the machine learning model. The information processing apparatus 100 estimates the element stiffness matrixes of a plurality of elements in parallel by using a plurality of cores included in the GPU 104.

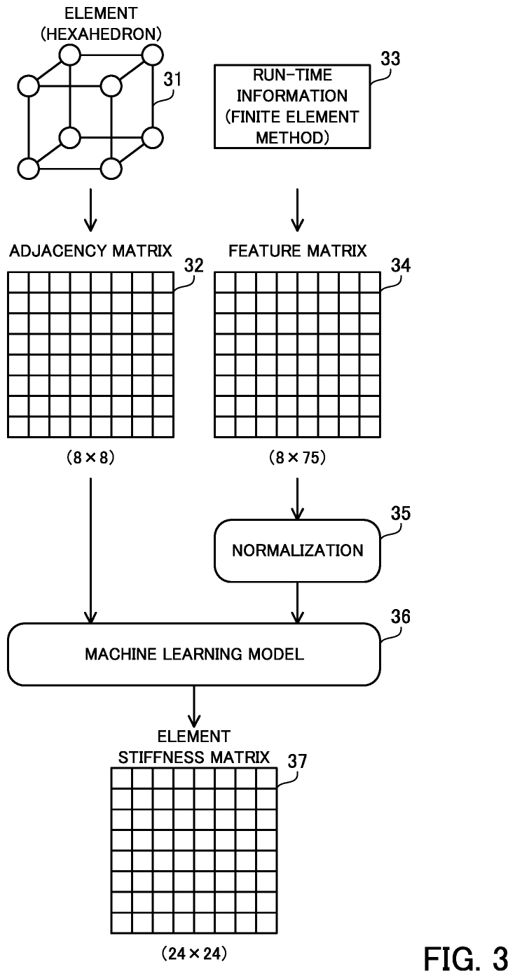

FIG. 3 illustrates a procedure example of estimation of an element stiffness matrix.

The information processing apparatus 100 generates an adjacency matrix 32 from an element 31. The element 31 is a hexahedron including eight nodes. However, the element 31 may be a tetrahedron including four nodes.

The adjacency matrix 32 is a square matrix, and the length of the individual side is 8. A single row corresponds to a single node, and a single column corresponds to a single node. The adjacency matrix 32 indicates an adjacency relationship among the eight nodes included in the element 31. For example, a coefficient corresponding to two node indicates 1 when an edge is present between these two nodes. Otherwise, the coefficient indicates 0. As will be described below, according to the second embodiment, the information processing apparatus 100 may generate the adjacency matrix 32 by assuming the element 31 as a complete graph in which all the nodes are connected mutually.

In addition, the information processing apparatus 100 generates a feature matrix 34 from run-time information 33 based on a finite element method. The run-time information 33 is various kinds of information obtained when an overall stiffness matrix is generated based on the time marching method and Newton-Raphson method. The run-time information 33 may include numerical values given by the user in the first time step. The run-time information 33 may include numerical values computed in the previous time step. The run-time information 33 may include numerical values computed in the previous iteration in the same time step.

The feature matrix 34 is a matrix of eight rows and 75 columns. A single row corresponds to a single node and represents a single feature vector. Thus, the feature matrix 34 includes 8 feature vectors corresponding to 8 nodes. The 75 dimensional feature vectors will be described in detail below. The information processing apparatus 100 executes normalization 35 on the feature matrix 34. The information processing apparatus 100 normalizes the feature amounts included in the feature matrix 34 per dimension. The normalized feature amounts each indicate a value between −1 and 1, inclusive.

The information processing apparatus 100 enters the adjacency matrix 32 and the feature matrix 34 on which the normalization 35 has been performed to a machine learning model 36. The machine learning model 36 is a graph convolutional neural network. The machine learning model 36 includes graph convolutional layers, each of which performs a convolutional operation on the feature vectors of the eight nodes. The individual graph convolutional layer converts the feature vector of a certain node into a feature vector by using a parameter value, and also converts each of the feature vectors of other nodes adjacent to the certain node into a feature vector by using a parameter value. Next, the graph convolutional layer adds the converted feature vectors of the adjacent nodes to the feature vector of the certain node. The parameter values are trained through machine learning. The individual graph convolutional layer determines the adjacency relationship between nodes based on the adjacency matrix 32. As described above, the adjacency relationship indicated by the adjacency matrix 32 could not match the presence or absence of the actual edges of the element 31.

The machine learning model 36 outputs an element stiffness matrix 37. The element stiffness matrix 37 indicates the stiffness of the element 31. The length of one side of the element stiffness matrix 37 is a sum of the degrees of freedom of the displacement of the eight nodes. Each of the eight nodes included in the element 31 has three independent variables in the x, y, and z directions. Thus, the element stiffness matrix 37 is a square matrix, and the length of the individual side is 24.

The information processing apparatus 100 generates an overall stiffness matrix by synthesizing a plurality of element stiffness matrixes of a plurality of elements. First, the information processing apparatus 100 initializes all the coefficients included in the overall stiffness matrix to zero. The overall stiffness matrix represents the overall stiffness of the mesh data including the plurality of elements. The length of one side of the overall stiffness matrix is a sum of the degrees of freedom of the displacement of the plurality of nodes included in the mesh data.

After the element stiffness matrix 37 corresponding to the element 31 is generated, the information processing apparatus 100 reads out a coefficient corresponding to a single row and a single column of the element stiffness matrix 37 from the element stiffness matrix 37. The information processing apparatus 100 determines a row representing the same independent variable as that of the single row and determines a column representing the same independent variable as that of the single column from the overall stiffness matrix. Next, the information processing apparatus 100 adds the read coefficient to the coefficient corresponding to the determined row and column. The information processing apparatus 100 performs this addition process on all the element stiffness matrixes of all the elements.

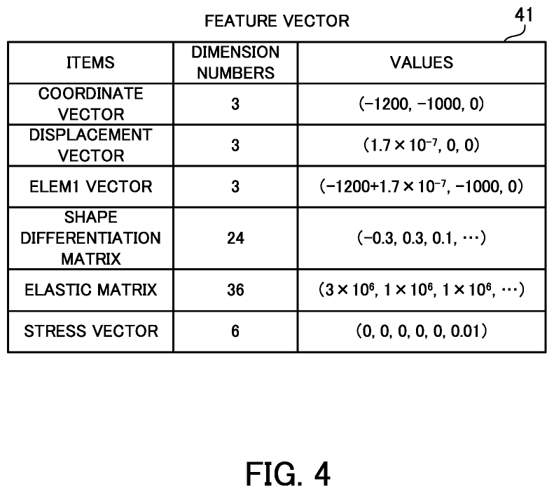

FIG. 4 illustrates an example of a feature vector.

The information processing apparatus 100 generates a 75 dimensional feature vector 41 for each node. The feature vector 41 is a vector in which a coordinate vector, a displacement vector, an ELEM1 vector, a shape differentiation matrix, an elastic matrix, and a stress vector are synthesized. The examples of the feature amounts included in the feature vector 41 illustrated in FIG. 4 are those that have not yet been normalized.

The coordinate vector indicates the initial location of a node when the simulation is started, that is, when the first time step is started. The coordinate vector indicates coordinates in a Cartesian coordinate system and includes x, y, and z components. The number of dimensions of the coordinate vector is 3.

The displacement vector indicates the initial displacement amount of the node when the current time step is started. The initial displacement amount in the current time step is, for example, a numerical value obtained by adding the increase of the displacement amount computed in the previous time step to the initial displacement amount in the previous time step. The displacement vector includes the x, y, and z components of the displacement amount of the node. The number of dimensions of the displacement vector is 3.

The ELEM1 vector indicates the location of the node when the current time step is started. The ELEM1 vector is computed by adding the displacement vector to the coordinate vector. The ELEM1 vector indicates coordinates in the Cartesian coordinate system and includes the x, y, and z components. The number of dimensions of the ELEM1 vector is 3. Depending on the configuration of the machine learning model 36, the ELEM1 vector may be absent in the feature vector 41.

The shape differentiation matrix represents a derivative of an interpolation function used in the finite element method. The interpolation function is a function for estimating physical amounts at any point inside the element from physical amounts assigned to a node, and may be referred to as a shape function. In the case of a hexahedral element, there are eight peer nodes for each node. The differential of the interpolation function between two nodes is expressed three dimensionally. Thus, the shape differentiation matrix is a matrix of 8 rows and 3 columns. Written in series, the shape differentiation matrix of 8 rows and 3 columns in the feature vector 41 is expressed a 24 dimensional vector.

The elastic matrix includes the elastic modulus of the node. The elastic matrix may be referred to as an elastic modulus matrix. The elastic matrix is computed based on material attributes of the object. Because a strain vector and the stress vector are 6 dimensional vectors, the elastic matrix is a matrix of 6 rows and 6 columns. Written in series, this elastic matrix of 6 rows and 6 columns in the feature vector 41 is expressed as a 36 dimensional vector.

The stress vector indicates the initial stress applied to the node when the current time step is started.

The initial stress in the current time step is a numerical value obtained by adding the increase of the stress computed in the previous time step to the initial stress in the previous time step, for example. The stress vector includes an x component σₓ, a y component σ_{y}, a z component σ₁, an xy component σ_{xy}, a yz component σ_{yz}, and a zx component σ_{zx} of the stress applied to the node. The number of dimensions of the stress vector is 6.

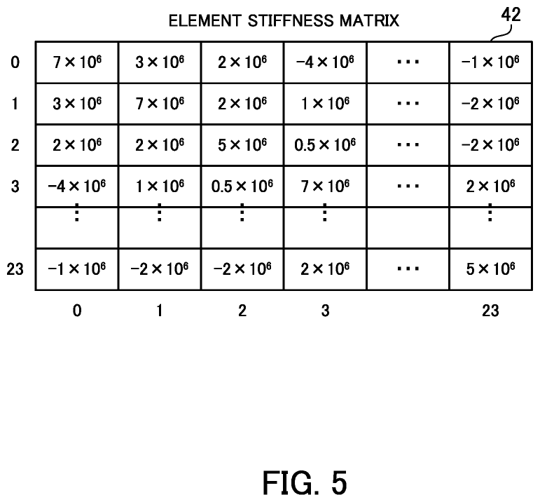

FIG. 5 illustrates an example of an element stiffness matrix.

An element stiffness matrix 42 is a matrix that is output from the machine learning model 36 and corresponds to the above element stiffness matrix 37. The element stiffness matrix 42 is a square matrix of 24 rows and 24 columns. The element stiffness matrix 42 is a symmetric matrix in which the coefficient of the i-th row and the j-th column is the same as the coefficient of the j-th row and the i-th column due to its physical characteristics. In addition, the element stiffness matrix 42 is a sparse matrix including larger values around its diagonal line and including zeros and smaller values away from the diagonal line. The information processing apparatus 100 generates a plurality of element stiffness matrixes in parallel by using a plurality of GPU cores.

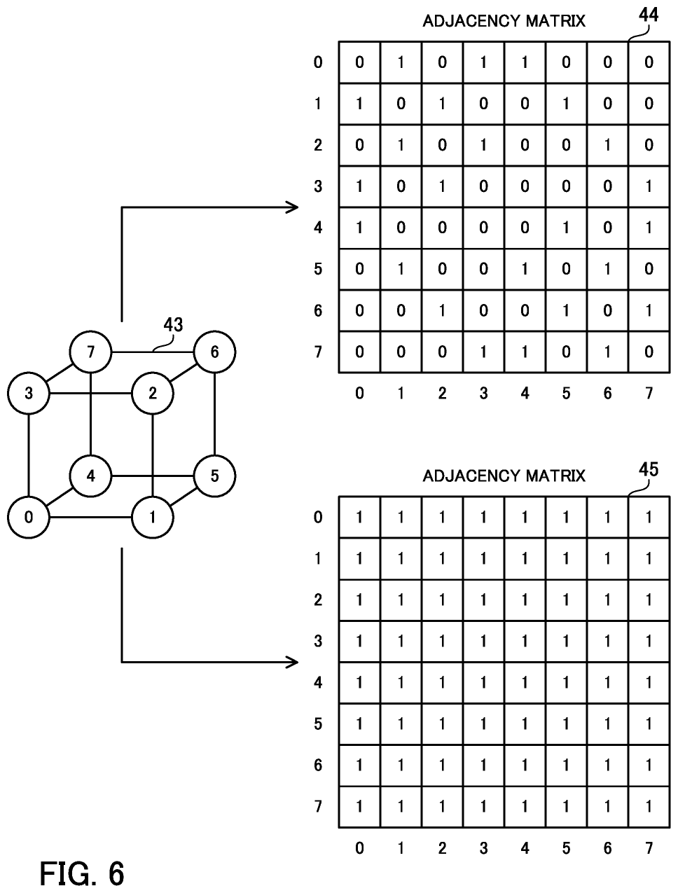

FIG. 6 illustrates examples of adjacency matrixes.

The information processing apparatus 100 generates an adjacency matrix 44 or an adjacency matrix 45 from an element 43. The element 43 corresponds to the above element 31. The adjacency matrixes 44 and 45 each correspond to the above adjacency matrix 32. The adjacency matrixes 44 and 45 are each a square matrix of 8 rows and 8 columns.

The adjacency matrix 44 is a sparse matrix that defines an adjacency relationship among the 8 nodes included in the element 43 based on the presence or absence of the edges of the element 43. Regarding a coefficient determined by a row corresponding to one node and a column corresponding to another node, if these two nodes are directly connected by an edge, this coefficient is 1. If these two nodes are not directly connected by an edge, the coefficient is 0. Because the element 43 is a hexahedron, three of the coefficients in a single row of the adjacency matrix 44 indicate “1”. The coefficients on an individual diagonal line may be set to “1”. That is, if two nodes are the same, “1” may be assigned as the coefficient.

In contrast, the adjacency matrix 45 is a dense matrix generated by assuming that the 8 nodes included in the element 43 form a complete graph. All the coefficients included in the adjacency matrix 45 are “1”. In the case of this adjacency matrix 45, any two nodes included in the same element are considered as being adjacent to each other. According to the second embodiment, the information processing apparatus 100 uses a dense matrix such as the adjacency matrix 45 as the adjacency matrix, instead of a sparse matrix such as the adjacency matrix 44.

The information processing apparatus 100 is able to reproduce the F-bar method based on the finite element method more accurately by propagating feature amounts not only between two nodes that share an edge but also between two nodes that do not share an edge in the same element. Thus, by using a dense matrix such as the adjacency matrix 45, the accuracy of the element stiffness matrix is improved.

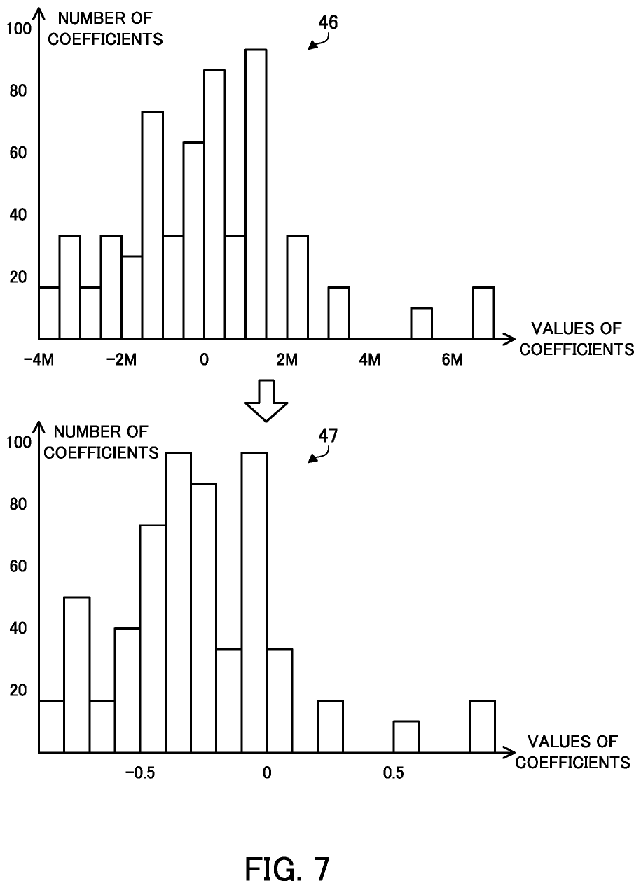

FIG. 7 illustrates an example of normalization of an element stiffness matrix.

When a machine learning model is trained, the information processing apparatus 100 normalizes a feature matrix that is input to the machine learning model and an element stiffness matrix that is output by the machine learning model. In addition, when an element stiffness matrix is estimated, the information processing apparatus 100 normalizes a feature matrix that is input to the machine learning model, and reconstructs an element stiffness matrix that is output by the machine learning model into the original scale.

For the normalization, a Min-Max method is used, for example. When a machine learning model is trained, the information processing apparatus 100 determines a maximum value and a minimum value for each of the 75 dimensions included in a feature vector, and determines a conversion method such that the maximum value becomes +1 and the minimum value becomes −1. The information processing apparatus 100 records the conversion method for each of the 75 dimensions. When an element stiffness matrix is estimated, the information processing apparatus 100 normalizes a feature amount in accordance with the recorded conversion method for each of the 75 dimensions included in the feature vector.

In addition, when a machine learning model is trained, the information processing apparatus 100 determines a maximum value and a minimum value of the coefficients included in an element stiffness matrix, and determines a conversion method such that the maximum value becomes +1 and the minimum value becomes −1. The information processing apparatus 100 records the coefficient conversion method.

When an element stiffness matrix is estimated, the information processing apparatus 100 performs inverse conversion on the normalized coefficients included in the element stiffness matrix that is output by the machine learning model in accordance with the recorded conversion method. By normalizing the input and output of the machine learning model, the estimation accuracy of the machine learning model is improved.

For example, a normalized value is computed as follows. By defining x′=−1+2(x−min)/(max−min) where x is a value before the normalization, x′ is a value after the normalization, max is a maximum value, and min is a minimum value, the value range after the normalization becomes [−1, +1].

A graph 46 indicates a relationship between the values of the coefficients included in an element stiffness matrix and the number of coefficients. The horizontal axis represents coefficient values that have not yet been normalized, and the vertical axis represents the number of coefficients. A graph 47 indicates a relationship between the values of the coefficients in the same element stiffness matrix used for the graph 46 and the number of coefficients. However, the horizontal axis represents coefficient values that have been normalized, and the vertical axis represents the number of coefficients. By performing linear transformation in accordance with a Min-Max method, it is possible to set the coefficient values within a range between −1 and +1, inclusive, while maintaining their distribution.

Next, a graph convolutional neural network will be described. The graph convolutional neural network includes fully connected layers and graph convolutional layers. The individual fully connected layer converts the feature vector of an individual node separately from the other nodes. In contrast, the individual graph convolutional layer converts the feature vector of an individual node by referring to the feature vectors of the adjacent nodes indicated by the adjacency matrix.

For example, the individual fully connected layer converts the feature vectors as follows, assuming that x is a feature matrix before the conversion, y is a feature matrix after the conversion, W is a weight matrix, and b is an offset vector. A single row in the feature matrixes x and y corresponds to a single node. The individual fully connected layer performs a matrix computation expressed by y=xW+b. The weight matrix W and the offset vector b are shared by all the nodes, and the coefficients of the weight matrix W and the offset vector b are determined through machine learning. The j-th column of the weight matrix W is a weight vector used for converting the j-th feature amount of a feature vector.

For example, the individual graph convolutional layer converts a feature vector as follows, assuming that A is an adjacency matrix and z is a feature matrix after the conversion. The individual graph convolutional layer performs a matrix computation expressed by z=Ay=A(xW+b). Thus, after performing the same matrix computation as that of the fully connected layer, the individual graph convolutional layer performs an additional matrix computation. By computing a linear sum of some or all of the feature amounts in the j-th column of the feature matrix y, the j-th feature amount of a feature vector is computed.

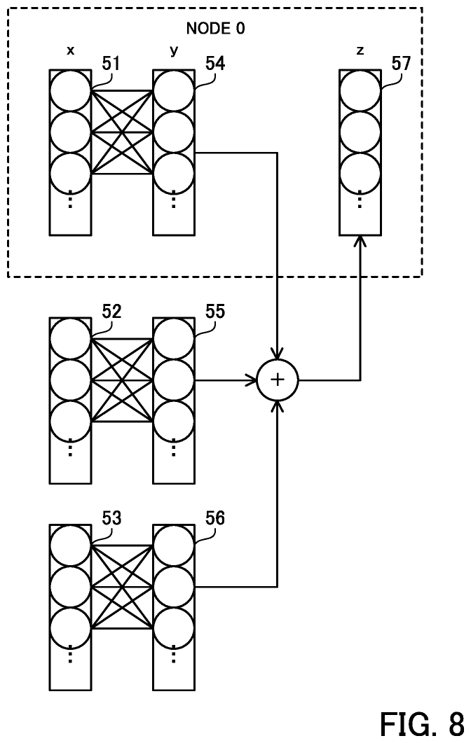

FIG. 8 illustrates an example of a graph convolutional operation.

A feature vector 51 is the feature vector of the target node. Feature vectors 52 and 53 are the feature vectors of nodes that are included in the same element with the target node and that are adjacent to the target node. A graph convolutional layer converts the feature vector 51 into a feature vector 54 by using the feature amounts included in the feature vector 51. Similarly, the graph convolutional layer converts the feature vector 52 into a feature vector 55 by using the feature amounts included in the feature vector 52, and converts the feature vector 53 into a feature vector 56 by using the feature amounts included in the feature vector 53.

The graph convolutional layer adds the feature vectors 55 and 56 to the feature vector 54, to generate a feature vector 57. The feature vector 57 is the feature vector of the target node obtained by the conversion of the feature vector 51 based on a graph convolutional operation. If a dense adjacency matrix as described above is used, each node is adjacent to the other seven nodes.

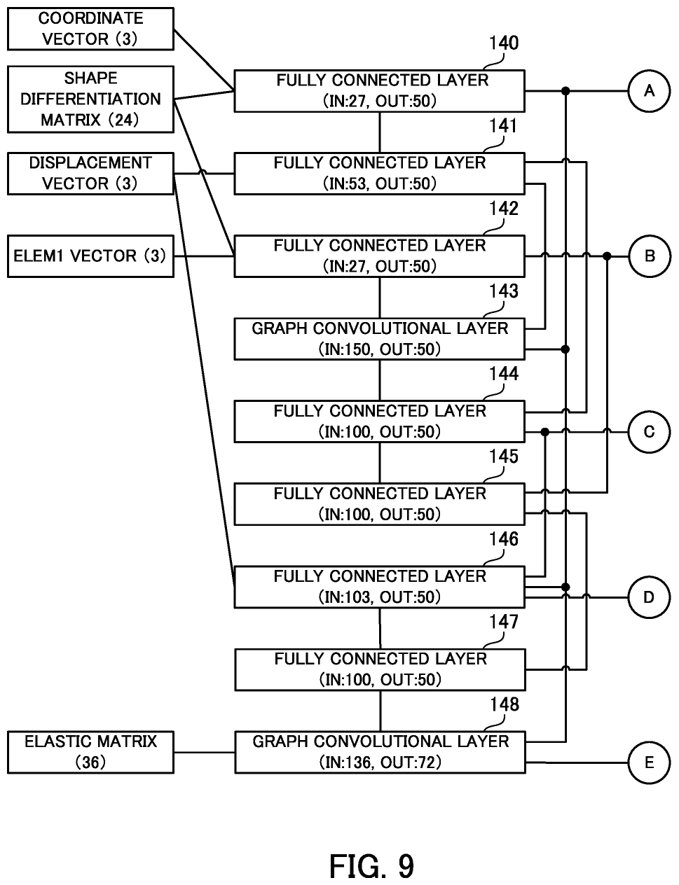

FIG. 9 illustrates the first half of a construction example of a machine learning model.

Hereinafter, an example of the machine learning model used in the second embodiment will be described. The machine learning model includes fully connected layers 140, 141, 142, 144, 145, 146, and 147 and graph convolutional layers 143 and 148.

The fully connected layer 140 has a 27 dimensional input and a 50 dimensional output. The fully connected layer 140 receives a 3 dimensional coordinate vector and a 24 dimensional shape differentiation matrix and outputs a 50 dimensional vector, for each of the eight nodes. The fully connected layer 141 has a 53 dimensional input and a 50 dimensional output. The fully connected layer 141 receives a 3 dimensional displacement vector and the output of the fully connected layer 140 and outputs a 50 dimensional vector, for each of the eight nodes.

The fully connected layer 142 has a 27 dimensional input and a 50 dimensional output. The fully connected layer 142 receives a 24 dimensional shape differentiation matrix and a 3 dimensional ELEM1 vector and outputs a 50 dimensional vector, for each of the eight nodes. The graph convolutional layer 143 has a 150 dimensional input and a 50 dimensional output. The graph convolutional layer 143 receives the output of the fully connected layers 140, 141, and 142, the output corresponding to the eight nodes, as a matrix of 8 rows and 150 columns, and outputs a 50 dimensional vector corresponding to the eight nodes as a matrix of 8 rows and 50 columns.

The fully connected layer 144 is a 100 dimensional input and a 50 dimensional output. The fully connected layer 144 receives the output of the fully connected layer 141 and the graph convolutional layer 143 and outputs a 50 dimensional vector, for each of the eight nodes. The fully connected layer 145 has a 100 dimensional input and a 50 dimensional output. The fully connected layer 145 receives the output of the fully connected layers 142 and 144 and outputs a 50 dimensional vector, for each of the eight nodes.

The fully connected layer 146 has a 103 dimensional input and a 50 dimensional output. The fully connected layer 146 receives a 3 dimensional displacement vector and the output of the fully connected layers 140 and 144 and outputs a 50 dimensional vector, for each of the eight nodes. The fully connected layer 147 is a 100 dimensional input and a 50 dimensional output. The fully connected layer 147 receives the output of the fully connected layers 145 and 146 and outputs a 50 dimensional vector, for each of the eight nodes.

The graph convolutional layer 148 has a 136 dimensional input and a 72 dimensional output. The graph convolutional layer 148 receives a 36 dimensional elastic matrix corresponding to the eight nodes and the output of the fully connected layers 140 and 147 as a matrix of 8 rows and 136 columns, and outputs a 72 dimensional vector corresponding to the eight nodes as a matrix of 8 rows and 72 columns.

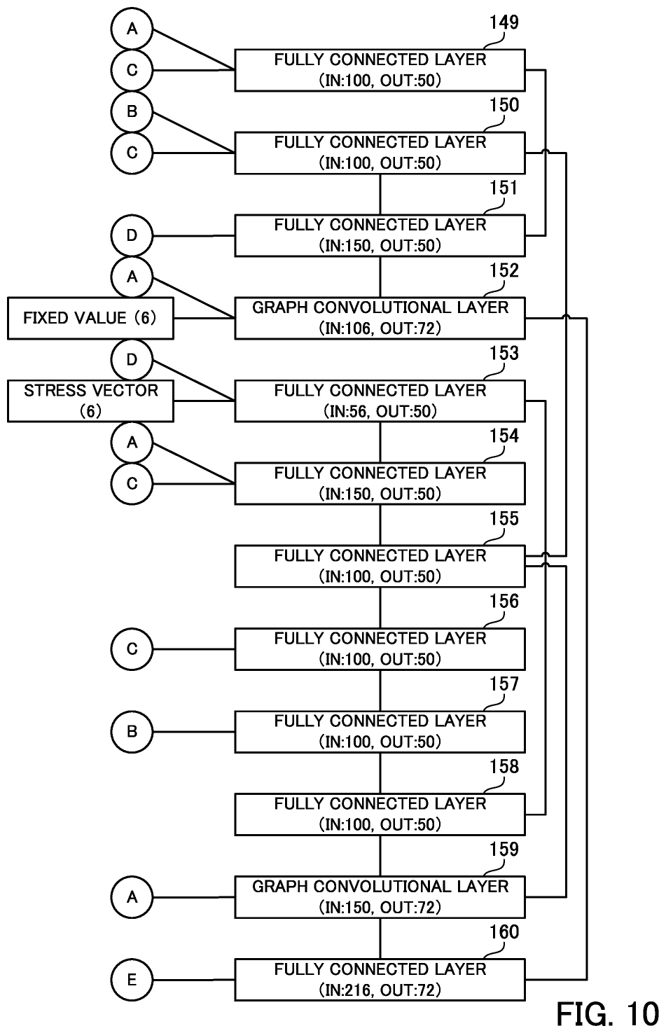

FIG. 10 illustrates the second half of the construction example of the machine learning model.

The machine learning model further includes fully connected layers 149, 150, 151, 153, 154, 155, 156, 157, 158, and 160 and graph convolutional layers 152 and 159.

The fully connected layer 149 has a 100 dimensional input and a 50 dimensional output. The fully connected layer 149 receives the output of the fully connected layers 140 and 144 and outputs a 50 dimensional vector, for each of the eight nodes. The fully connected layer 150 has a 100 dimensional input and a 50 dimensional output. The fully connected layer 150 receives the output of the fully connected layers 142 and 144 and outputs a 50 dimensional vector, for each of the eight nodes.

The fully connected layer 151 has a 150 dimensional input and a 50 dimensional output. The fully connected layer 151 receives the output of the fully connected layers 146, 149, and 150 and outputs a 50 dimensional vector, for each of the eight nodes. The graph convolutional layer 152 has a 106 dimensional input and a 72 dimensional output. The graph convolutional layer 152 receives a 6 dimensional fixed value corresponding to the eight nodes and the output of the fully connected layers 140 and 151 as a matrix of 8 rows and 106 columns, and outputs a 72 dimensional vector corresponding to the eight nodes as a matrix of 8 rows and 72 columns.

The fully connected layer 153 has a 56 dimensional input and a 50 dimensional output. The fully connected layer 153 receives a 6 dimensional stress vector and the output of the fully connected layer 146 and outputs a 50 dimensional vector, for each of the eight nodes. The fully connected layer 154 has a 150 dimensional input and a 50 dimensional output. The fully connected layer 154 receives the output of the fully connected layers 140, 144, and 153 and outputs a 50 dimensional vector, for each of the eight nodes.

The fully connected layer 155 has a 100 dimensional input and a 50 dimensional output. The fully connected layer 155 receives the output of the fully connected layers 150 and 154 and outputs a 50 dimensional vector, for each of the eight nodes. The fully connected layer 156 has a 100 dimensional input and a 50 dimensional output. The fully connected layer 156 receives the output of the fully connected layers 144 and 155 and outputs a 50 dimensional vector, for each of the eight nodes.

The fully connected layer 157 has a 100 dimensional input and a 50 dimensional output. The fully connected layer 157 receives the output of the fully connected layers 142 and 156 and outputs a 50 dimensional vector, for each of the eight nodes. The fully connected layer 158 has a 100 dimensional input and a 50 dimensional output. The fully connected layer 158 receives the output of the fully connected layers 153 and 157 and outputs a 50 dimensional vector, for each of the eight nodes.

The graph convolutional layer 159 has a 150 dimensional input and a 72 dimensional output. The graph convolutional layer 159 receives the output of the fully connected layers 140, 155, and 158, the output corresponding to the eight nodes, as a matrix of 8 rows and 150 columns, and outputs a 72 dimensional vector corresponding to the eight nodes, as a matrix of 8 rows and 72 columns.

The fully connected layer 160 has a 216 dimensional input and a 72 dimensional output. The fully connected layer 160 receives the output of the graph convolutional layers 148, 152, and 159, the output corresponding to the eight nodes, as a matrix of 8 rows and 216 columns, and outputs a matrix of 8 rows and 72 columns. By rearranging the coefficients in this matrix, the information processing apparatus 100 generates an element stiffness matrix of 24 rows and 24 columns.

Next, training of a machine learning model will be described. The information processing apparatus 100 generates training data for training a machine learning model by executing existing finite element method software. The information processing apparatus 100 traps a time point immediately before a matrix is generated by finite element method software and extracts run-time information held at that time. The run-time information may be input data used for generating the matrix. In addition, the information processing apparatus 100 traps a time point immediately after a matrix is generated and extracts a generated element stiffness matrix.

The information processing apparatus 100 converts the extracted run-time information into a feature matrix of 8 rows and 75 columns and inserts the feature matrix into the training data as input data corresponding to an explanatory variable. In addition, the information processing apparatus 100 generates an adjacency matrix of eight rows and eight columns from an element and inserts the adjacency matrix into the training data as input data corresponding to an explanatory variable. In addition, the information processing apparatus 100 inserts an element stiffness matrix into the training data as a correct label corresponding to an objective variable.

The information processing apparatus 100 trains the machine learning model based on backpropagation, by using the training data. The information processing apparatus 100 enters the adjacency matrix and the feature matrix to the machine learning model and computes an error between the output of the machine learning model and the correct element stiffness matrix. The information processing apparatus 100 updates the parameter values included in the machine learning model such that the error is minimized.

A single generation of an element stiffness matrix is determined by a combination of a single division region, a single time step, a single non-linear iteration, and a single element. The information processing apparatus 100 is able to generate a single sample of training data from a single generation of an element stiffness matrix. Because the total number of these combinations is very large, the information processing apparatus 100 does not need to extract all the element stiffness matrixes generated in the structural analysis simulation. The time point at which an element stiffness matrix is extracted affects the accuracy of the training data and accordingly affects the accuracy of the machine learning model.

For example, the information processing apparatus 100 executes a 3D finite element method of 20,000 time steps on mesh data including two million nodes. During this method, the information processing apparatus 100 extracts run-time information about and element stiffness matrixes of 100 elements in a rank-0 MPI process, the first time step, and the second non-linear iteration. As a result, training data including 100 samples is generated. The information processing apparatus 100 trains a machine learning model by performing 100 iterations ×250 epochs, assuming that the mini batch size is 1.

Next, functions and processing procedures of the information processing apparatus 100 will be described.

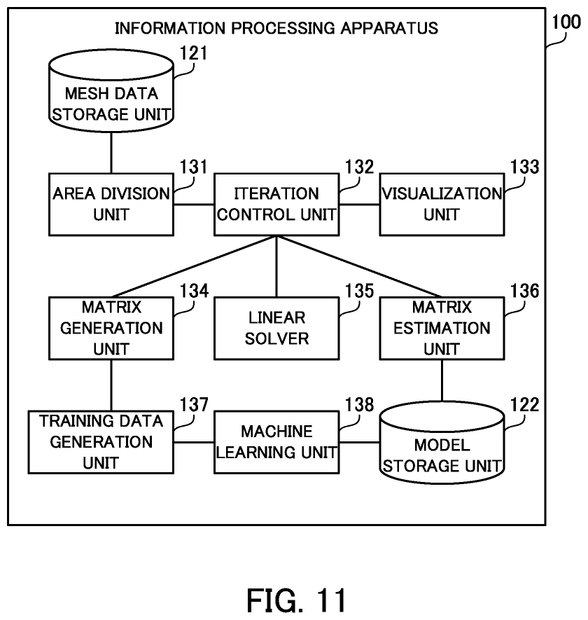

FIG. 11 is a block diagram illustrating a functional example of the information processing apparatus.

The information processing apparatus 100 includes a mesh data storage unit 121 and a model storage unit 122. These storage units are each implemented by using the RAM 102 or the HDD 103, for example. In addition, the information processing apparatus 100 includes an area division unit 131, an iteration control unit 132, a visualization unit 133, a matrix generation unit 134, a linear solver 135, a matrix estimation unit 136, a training data generation unit 137, and a machine learning unit 138. These processing units are each implemented by using the CPU 101, the GPU 104, and a program, for example.

The mesh data storage unit 121 stores mesh data generated by using CAD software. The mesh data includes a plurality of elements, each of which includes a plurality of nodes and a plurality of edges. The plurality of elements are obtained by dividing the shape of a simulation target object. In addition, the mesh data storage unit 121 stores setting information such as the material of the object and the external force applied to the object.

The model storage unit 122 stores a trained machine learning model. The machine learning model is a graph convolutional neural network as described above. The machine learning model may be trained by another information processing apparatus.

The area division unit 131 divides mesh data into a plurality of regions. The area division unit 131 starts a single MPI process for each division region and executes a plurality of MPI processes in parallel. The area division unit 131 may cause another information processing apparatus to execute these MPI processes.

The iteration control unit 132 controls the iteration based on the time marching method and Newton-Raphson method. The iteration control unit 132 calls the matrix generation unit 134 or the matrix estimation unit 136, to generate an overall stiffness matrix. The iteration control unit 132 defines a simultaneous linear equation by using the overall stiffness matrix, and calls the linear solver 135, to compute a solution of the simultaneous linear equation. By using the solution of the simultaneous linear equation, the iteration control unit 132 updates an approximate solution of a non-linear problem, such as a displacement vector or a stress vector.

The iteration control unit 132 determines whether the approximate solution has converged. If the approximate solution has not converged yet, the iteration control unit 132 defines the next linear problem for updating the approximate solution. If the approximate solution has converged, the iteration control unit 132 performs the next time step.

The visualization unit 133 visualizes the approximate solutions of a plurality of time steps computed by the iteration control unit 132. For example, the visualization unit 133 generates an image in which temporal change of the shape and stress of the 3D object is visualized, and displays the generated image on the display device 111. In addition, the visualization unit 133 may store the simulation result in a non-volatile storage such as the HDD 103 or may transmit the simulation result to another information processing apparatus.

The matrix generation unit 134 generates an overall stiffness matrix based on the F-bar method in response to a request from the iteration control unit 132. The matrix generation unit 134 generates an element stiffness matrix per element and generates an overall stiffness matrix by synthesizing the plurality of element stiffness matrixes of the plurality of elements. The matrix generation unit 134 generates the element stiffness matrixes by using the CPU 101.

The linear solver 135 computes a solution of a simultaneous linear equation in response to a request from the iteration control unit 132. For example, the linear solver 135 computes a solution of a large-scale simultaneous linear equation based on an iterative method, such as conjugate gradient (CG).

The matrix estimation unit 136 estimates an overall stiffness matrix in response to a request from the iteration control unit 132. The matrix estimation unit 136 is used, instead of the matrix generation unit 134. The matrix estimation unit 136 generates and normalizes, per element, a feature matrix from run-time information. The matrix estimation unit 136 estimates the normalized element stiffness matrixes by entering normalized feature matrixes to the machine learning model stored in the model storage unit 122. The matrix estimation unit 136 reconstructs the normalized element stiffness matrixes into their original scale and generates an overall stiffness matrix by synthesizing the plurality of element stiffness matrixes of the plurality of elements.

The matrix estimation unit 136 estimates element stiffness matrixes by using the GPU 104. The matrix estimation unit 136 generates a plurality of feature matrixes corresponding to a plurality of elements, forwards the plurality of feature matrixes to the GPU 104 at once, and causes the GPU 104 to estimate the plurality of element stiffness matrixes in parallel. The batch size indicating the number of elements processed in parallel depends on the number of cores of the GPU 104. The batch size may be specified by the user.

The training data generation unit 137 extracts run-time information and element stiffness matrixes from the matrix generation unit 134. The training data generation unit 137 converts the run-time information into a feature matrix, normalizes the feature matrix, and normalizes an element stiffness matrix. In addition, the training data generation unit 137 generates an adjacency matrix from an element. The training data generation unit 137 inserts a sample including the adjacency matrix, the normalized feature matrix, and the normalized element stiffness matrix into training data. In this way, the training data generation unit 137 generates training data including a plurality of samples.

The machine learning unit 138 trains a machine learning model by using training data generated by the training data generation unit 137 and stores the trained machine learning model in the model storage unit 122. The machine learning unit 138 may display the trained machine learning model on the display device 111 or may transmit the trained machine learning model to another information processing apparatus.

The machine learning unit 138 trains a machine learning model based on backpropagation. The machine learning unit 138 enters the adjacency matrix and the normalized feature matrix included in a sample to the machine learning model and computes an error between the output of the machine learning model and the normalized element stiffness matrix included in the sample. The machine learning unit 138 computes an error gradient of a parameter value held by an individual layer sequentially from the last layer to the initial layer and updates the parameter value by using the error gradient. The machine learning unit 138 computes the error and updates the parameter value repeatedly.

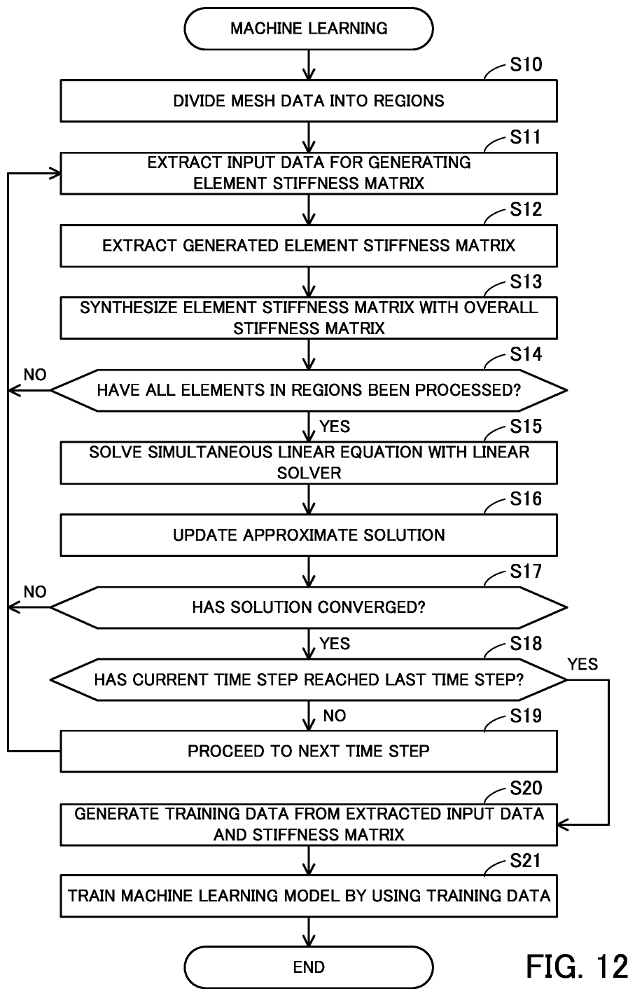

FIG. 12 is a flowchart illustrating a procedure example of machine learning.

(S10) The area division unit 131 divides mesh data into a plurality of regions. The following steps S11 to S19 may be executed on the plurality of regions in parallel.

(S11) The matrix generation unit 134 selects, from all the elements included in the division regions, one element for which an element stiffness matrix has not been generated yet. The training data generation unit 137 extracts, from the matrix generation unit 134, input data used for generating an element stiffness matrix. The training data generation unit 137 may extract input data only in certain iterations.

(S12) The matrix generation unit 134 generates an element stiffness matrix based on the F-bar method. The training data generation unit 137 extracts the generated element stiffness matrix from the matrix generation unit 134. The training data generation unit 137 may extract element stiffness matrixes only in certain iterations.

(S13) The matrix generation unit 134 synthesizes the element stiffness matrix generated in step S12 with an overall stiffness matrix corresponding to the division regions.

(S14) The matrix generation unit 134 determines whether all the elements included in the division regions have been processed. If all the elements have been processed, the present process proceeds to step S15. If there is an element that has not been processed yet, the present process returns to step S11, and one of the elements that have not been processed yet is selected.

(S15) The iteration control unit 132 defines a simultaneous linear equation by using the overall stiffness matrix. The linear solver 135 solves the simultaneous linear equation.

(S16) The iteration control unit 132 updates the approximate solution of a non-linear equation by using the Newton-Raphson method, based on the solution of the simultaneous linear equation computed in step S15.

(S17) The iteration control unit 132 determines whether the approximate solution of the non-linear equation has converged. If the approximate solution has converged, the present process proceeds to step S18. If the approximate solution has not converged yet, the present process returns to step S11, and steps S11 to S16 are performed again.

(S18) The iteration control unit 132 determines the current time step has reached the last time step. If the current time step has reached the last time step, the present process proceeds to step S20. If the current time step has not reached the last time step, the present process proceeds to step S19.

(S19) The iteration control unit 132 determines the displacement vector and the stress vector in the current time step and increments the time step by one. Next, the present process returns to step S11, and steps S11 to S17 are performed on the next time step.

(S20) The training data generation unit 137 generates a feature matrix from the input data extracted in step S11 and normalizes the feature matrix. In addition, the training data generation unit 137 normalizes the element stiffness matrix extracted in step S12. The training data generation unit 137 associates the normalized feature matrix and the normalized element stiffness matrix with each other, to generate training data.

(S21) The machine learning unit 138 trains a machine learning model by using the training data generated in step S20. The machine learning unit 138 stores the trained machine learning model.

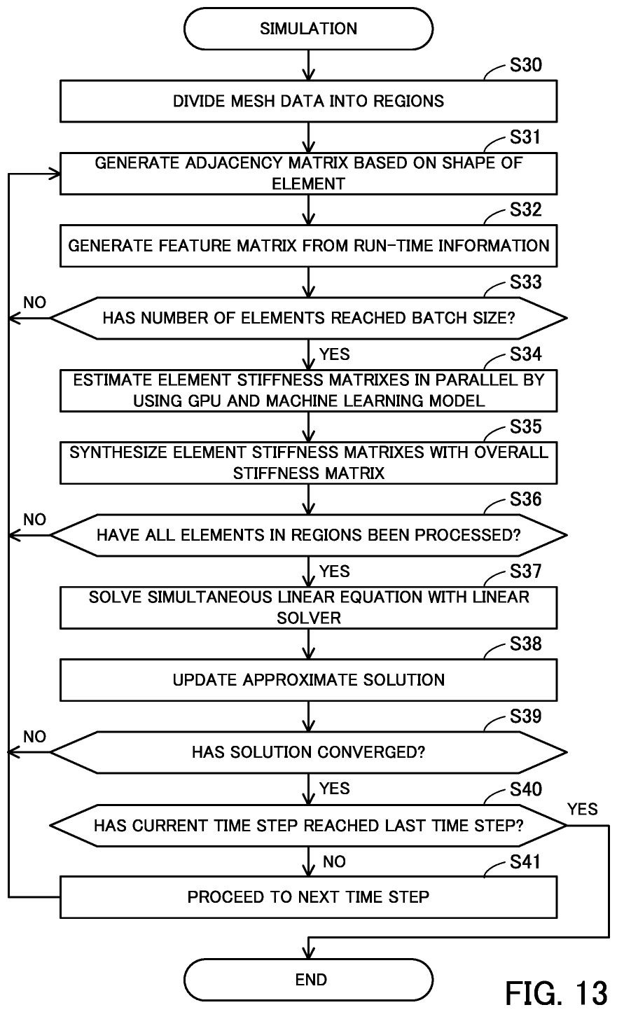

FIG. 13 is a flowchart illustrating a procedure example of a simulation.

(S30) The area division unit 131 divides mesh data into a plurality of regions. The following steps S31 to S41 may be executed on the plurality of regions in parallel.

(S31) The matrix estimation unit 136 selects, from all the elements included in the division regions, one element for which a feature matrix has not been generated yet. The matrix estimation unit 136 generates an adjacency matrix based on the shape of the element. For example, the matrix estimation unit 136 generates, from a hexahedron element, a dense matrix of 8 rows and 8 columns in which all the coefficients represent “1”, as the adjacency matrix.

(S32) The matrix estimation unit 136 generates a feature matrix from run-time information and normalizes the feature matrix.

(S33) The matrix estimation unit 136 determines whether the number of elements whose adjacency matrix and feature matrix have not been forwarded to the GPU 104 yet has reached the batch size. If the number of elements has reached the batch size, the present process proceeds to step S34. If the number of elements has not reached the batch size yet, the present process returns to step S31, and the next element is selected.

(S34) The matrix estimation unit 136 forwards the adjacency matrixes and the feature matrixes of the number of elements corresponding to the batch size to the GPU 104. The matrix estimation unit 136 causes the GPU 104 to estimate the element stiffness matrixes of the plurality of elements in parallel, by using a trained machine learning model.

(S35) The matrix estimation unit 136 reads out the element stiffness matrixes of the number of elements corresponding to the batch size from the GPU 104. The matrix estimation unit 136 synthesizes the element stiffness matrixes of the plurality of elements with the overall stiffness matrix corresponding to the division regions.

(S36) The matrix estimation unit 136 determines whether all the elements included in the division regions have been processed. If all the elements have been processed, the present process proceeds to step S37. If there is an element that has not been processed yet, the present process returns to step S31, and steps S31 to S35 are performed again.

(S37) The iteration control unit 132 defines a simultaneous linear equation by using the overall stiffness matrix. The linear solver 135 solves the simultaneous linear equation.

(S38) The iteration control unit 132 updates the approximate solution of a non-linear equation by using the Newton-Raphson method, based on the solution of the simultaneous linear equation computed in step S37.

(S39) The iteration control unit 132 determines whether the approximate solution of the non-linear equation has converged. If the approximate solution has converged, the present process proceeds to step S40. If the approximate solution has not converged yet, the present process returns to step S31, and steps S31 to S38 are performed again.

(S40) The iteration control unit 132 determines the current time step has reached the last time step. If the current time step has reached the last time step, the present simulation is ended. If the current time step has not reached the last time step, the present process proceeds to step S41.

(S41) The iteration control unit 132 determines the displacement vector and the stress vector in the current time step and increments the time step by one. Next, the present process returns to step S31, and steps S31 to S39 are performed on the next time step.

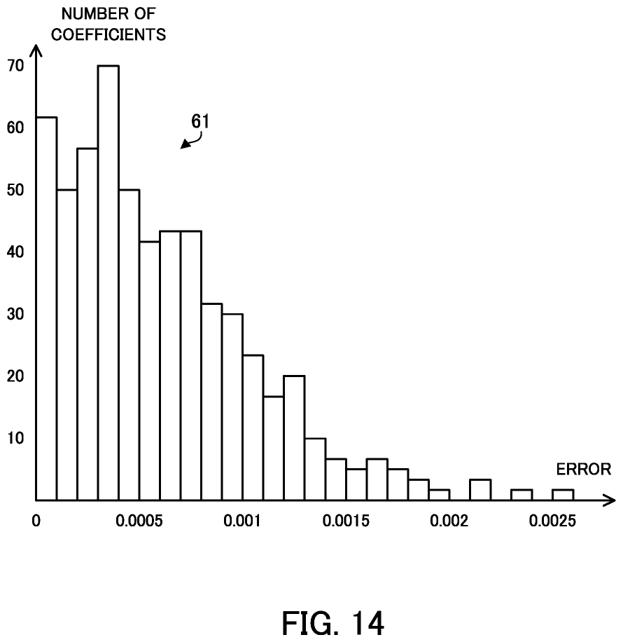

FIG. 14 is a graph illustrating an example of an estimation error of an element stiffness matrix.

A graph 61 indicates a relationship between an error and the number of coefficients about an estimated element stiffness matrix. The horizontal axis represents an error ratio between 0 and 1, inclusive, and the vertical axis represents, among the coefficients included in the element stiffness matrix, the number of coefficients having a certain estimation error. The maximum error of this certain element stiffness matrix is 0.0025 (0.25%), and the average error of this certain element stiffness matrix is 0.00058 (0.058%). Thus, the machine learning model is able to estimate an element stiffness matrix accurately. In this example, a dense matrix is used as the adjacency matrix.

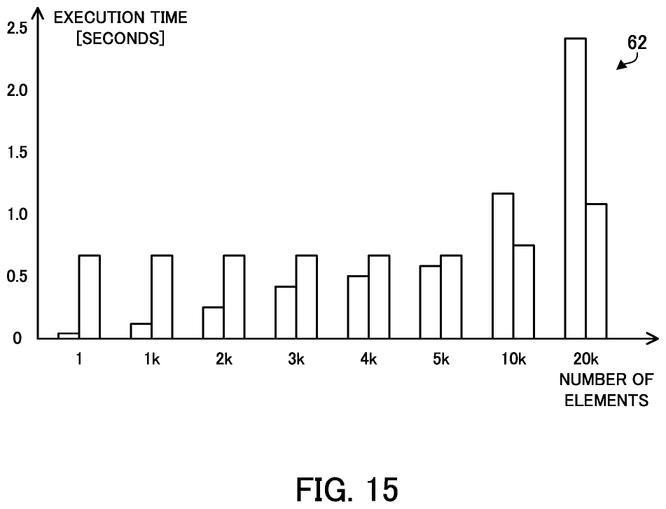

FIG. 15 is a graph illustrating an example of the execution time of generation of an element stiffness matrix.

A graph 62 represents a relationship between the number of elements and the execution time of generation of an element stiffness matrix. The horizontal axis represents the number of elements, and the vertical axis represents the execution time needed to generate an element stiffness matrix of a certain number of elements. The graph 62 indicates 1, 1000, 2000, 3000, 4000, 5000, 10000, and 20000 as the number of elements. There are two bars for the same number of elements. The left bar represents the execution time based on the F-bar method, and the right bar represents the execution time estimated by the machine learning model.

The execution time based on the F-bar method is the execution time needed for the CPU 101 to sequentially generate element stiffness matrixes of a certain number of elements. The execution time estimated by the machine learning model is the execution time needed for the GPU 104 to estimate element stiffness matrixes of the certain number of elements in parallel. In this case, the certain number of elements corresponds to the above batch size.

It is often the case that there is a communication overhead between the CPU 101 and the GPU 104 and that the computational performance of a GPU core is often lower than that of a CPU core. Thus, if a larger batch size is used, a better estimation speed is obtained. In the example of the graph 62, when the number of elements is 20000, the execution time is shortened from 2.44 to 1.12 seconds. That is, the execution speed based on the machine learning model is 2.18 times better than that based on the F-bar method. The upper limit of the batch size depends on the hardware specifications such as the number of cores of the GPU 104. For example, it is preferable that the batch size be approximately 10000 to 60000.

The matrix estimation according to the second embodiment may be applied to various kinds of scientific computations and various kinds of computer simulations, such as to thermal conduction, fluid dynamics, mass transport, and electromagnetic potential. In addition, while it is difficult for the F-bar method to generate an element stiffness matrix of a distorted element whose determinant represents negative values, the machine learning model is able to estimate an element stiffness matrix of such a distorted element.

As described above, the information processing apparatus 100 according to the second embodiment estimates an element stiffness matrix used for a structural analysis simulation based on a finite element method, by using a graph convolutional neural network. In this way, when generating an element stiffness matrix, the information processing apparatus 100 needs less load than the case in which the F-bar method is used. In addition, the information processing apparatus 100 needs a shorter execution time for the structural analysis simulation.

In addition, the information processing apparatus 100 is able to cause the GPU 104 to perform estimation based on a machine learning model, and it is possible to estimate the element stiffness matrixes of many elements in parallel by using many GPU cores. Thus, the speed of the structural analysis simulation is improved.

In addition, since the machine learning model is a graph convolutional neural network, by changing the adjacency matrix, the information processing apparatus 100 is able to process various topologies of elements, such as a tetrahedron and a hexahedron, with the same machine learning model. In addition, by assuming that the plurality of nodes included in a single element are adjacent to each other as in a complete graph, the information processing apparatus 100 generates a dense matrix as the adjacency matrix and uses this dense matrix in a graph convolutional operation. In this way, the machine learning model is able to simulate the computation based on the F-bar method and to accurately estimate an element stiffness matrix.

In addition, the information processing apparatus 100 estimates an element stiffness matrix from feature vectors including coordinate vectors, displacement vectors, ELEM1 vectors, shape differentiation matrixes, elastic matrixes, and stress vectors. In this way, the machine learning model is able to simulate the computation based on the F-bar method and to accurately estimate an element stiffness matrix.

In one aspect, the execution time of a structural analysis simulation is shortened.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A non-transitory computer-readable recording medium storing therein a computer program that causes a computer to execute a process comprising:
generating a feature vector for each node of a plurality of nodes included in an element in mesh data, based on a location of the each node, an elastic modulus at the each node, and stress applied to the each node;
entering feature vectors of the plurality of nodes to a trained machine learning model;
performing a convolutional operation on the feature vectors of the plurality of nodes; and
estimating an element stiffness matrix indicating stiffness of the element based on a result of the convolutional operation.

2. The non-transitory computer-readable recording medium according to claim 1, wherein the machine learning model is a graph convolutional neural network.

3. The non-transitory computer-readable recording medium according to claim 1, wherein the estimating includes estimating a plurality of element stiffness matrixes corresponding to a plurality of elements in parallel by using a graphics processing unit (GPU).

4. The non-transitory computer-readable recording medium according to claim 1,
wherein the process further includes generating an adjacency matrix indicating that each of the plurality of nodes in the element is adjacent to all other nodes, and
wherein the convolutional operation is performed based on the adjacency matrix.

5. The non-transitory computer-readable recording medium according to claim 1, wherein information about the location includes an initial location of the each node and a displacement amount of the each node computed in a previous time step on a simulation.

6. The non-transitory computer-readable recording medium according to claim 1, wherein the generating includes generating the feature vector based on a shape differentiation matrix indicating differentiation of an interpolation function between the each node and another node, in addition to the location, the elastic modulus, and the stress.

7. The non-transitory computer-readable recording medium according to claim 1, wherein the process further includes
generating another feature vector for each of a plurality of other nodes included in another element, performing a finite element method simulation, generating another element stiffness matrix corresponding to the another element, and training the machine learning model by using training data including the another feature vector and the another element stiffness matrix.

8. A structural analysis method comprising:
generating, by a processor, a feature vector for each node of a plurality of nodes included in an element in mesh data, based on a location of the each node, an elastic modulus at the each node, and stress applied to the each node;
entering, by the processor, feature vectors of the plurality of nodes to a trained machine learning model;
performing, by the processor, a convolutional operation on the feature vectors of the plurality of nodes; and
estimating, by the processor, an element stiffness matrix indicating stiffness of the element based on a result of the convolutional operation.

9. An information processing apparatus comprising:
a memory configured to store a trained machine learning model; and
a processor coupled to the memory and the processor configured to:
generate a feature vector for each node of a plurality of nodes included in an element in mesh data, based on a location of the each node, an elastic modulus at the each node, and stress applied to the each node;
entering feature vectors of the plurality of nodes to the machine learning model;
performing a convolutional operation on the feature vectors of the plurality of nodes; and
estimating an element stiffness matrix indicating stiffness of the element based on a result of the convolutional operation.
